(19) United States
(12) Patent Application Publication
(10) Pub. No.: US 2025/0029939 A1
(43) Pub. Date: Jan. 23, 2025

(54) SEMICONDUCTOR DEVICE AND SEMICONDUCTOR MODULE

(71) Applicant: FUJI ELECTRIC CO., LTD., Kawasaki-shi (JP)

(72) Inventors: Motohito HORI, Matsumoto-city (JP); Yoshinari IKEDA, Matsumoto-city (JP)

(73) Assignee: FUJI ELECTRIC CO., LTD., Kawasaki-shi (JP)

(21) Appl. No.: 18/677,610

(22) Filed: May 29, 2024

(30) Foreign Application Priority Data
Jul. 18, 2023 (JP) 2023-116834

(51) Int. Cl. H01L 23/64; H01L 23/373; H01L 25/07

(52) U.S. Cl. CPC H01L 23/645; H01L 23/3735; H01L 25/072

(57) ABSTRACT

A semiconductor module includes a wiring terminal having an insulating layer, first and second conductive layers sandwiching the insulating layer therebetween, and a semiconductor module. The insulating layer has an insulating peripheral side that extends more outwardly than a conductive peripheral side of each of the first and second conductive layers. The semiconductor module includes a semiconductor chip, first and second terminals respectively electrically connected to the semiconductor chip, and a fixing part. The first and second terminals include first and second end parts having first and second contact surfaces in contact with the first and second conductive layers, respectively. The fixed part has a basal surface facing the insulating peripheral side, having a recess between the first and second end parts into which the insulating peripheral side is inserted.

### CROSS-REFERENCE TO RELATED APPLICATION

This application is based upon and claims the benefit of priority of the prior Japanese Patent Application No. 2023-116834, filed on Jul. 18, 2023, the entire contents of which are incorporated herein by reference.

### BACKGROUND OF THE INVENTION

### 1. Field of the Invention

The embodiment discussed herein relates to a semiconductor device and a semiconductor module.

### 2. Background of the Related Art

A semiconductor device includes semiconductor

modules and a capacitor connected to the semiconductor modules (for example, see Japanese Laid-open Patent Publication No. 2021-141729). An individual semiconductor module includes a semiconductor chip, positive and negative terminals, and a sealing member that seals the semiconductor chip, and the positive and negative terminals extend to the outside from one surface of the sealing member (for example, see Japanese Laid-open Patent Publication No. 2019-117944, International Publication Pamphlet No. 2017/119226, and International Publication Pamphlet No. 2014/002442). In addition, there has been proposed a method for connecting a bus-bar to a semiconductor module without fastening that uses a bolt (for example, see International Publication Pamphlet No. 2015/162712).

### SUMMARY OF THE INVENTION

According to one aspect, there is provided a semiconductor device including: a wiring terminal that includes an insulating layer, a first conductive layer formed on one main surface of the insulating layer, and a second conductive layer r formed on another main surface of the insulating layer, the insulating layer having an insulating peripheral side that extends more outwardly than a conductive peripheral side of each of the first conductive layer and the second conductive layer; and a semiconductor module, wherein the semiconductor module includes a semiconductor chip having a first electrode and a second electrode, a first terminal electrically connected to the first electrode, the first terminal including a first end part having a first contact surface in contact with the first conductive layer of the wiring terminal a second terminal electrically connected to the second electrode, the second terminal including a second end part having a second contact surface, the second contact surface being away from the first end part, being parallel to the first contact surface and being in contact with the second conductive layer of the wiring terminal, and a fixed part, having a basal surface which faces the insulating peripheral side of the wiring terminal and from which the first end part and the second end part extend to an outside of the fixed part in a same direction, the fixing part fixing inside thereof positions of the first terminal and the second terminal with respect to a position of the semiconductor chip, and having a recess in the basal surface between the first end part and the second end part, the insulating peripheral side of the insulating layer of the wiring terminal being inserted into the recess.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to an embodiment;

FIG. 2 is a side view (X-Z surface) of the semiconductor device according to the embodiment;

FIG. 3 is a perspective view of a semiconductor

module included in the semiconductor device according to the embodiment;

FIG. 4 is a side view (X-Z surface) of the semiconductor module included in the semiconductor device according to the embodiment;

FIG. 5 is a side view (Z-Y surface) of the semiconductor module included in the semiconductor device according to the embodiment;

FIG. 6 is a rear view of the semiconductor module included in the semiconductor device according to the embodiment;

FIG. 7 is a plan view of a semiconductor unit included in a semiconductor module according to the embodiment;

FIG. 8 is a sectional view of the semiconductor unit included in the semiconductor module according to the embodiment;

FIG. 9 is a side view (Z-Y surface) of the semiconductor unit included in the semiconductor module according to embodiment;

FIG. 10 is a plan view of an insulating circuit board included in the semiconductor module according to the embodiment;

FIG. 11 is a perspective view of a capacitor included in the semiconductor device according to the embodiment;

FIG. 12 is a sectional view of a coupling part of the semiconductor device according to the embodiment;

FIG. 13 is a side view (X-Z surface) of a semiconductor device according to a reference example;

FIG. 14 is a side view (Z-Y surface) of a semiconductor module included in a semiconductor device according to the embodiment (modification 1);

FIG. 15 is a sectional view of a coupling part of the semiconductor device according to the embodiment (modification 1);

FIG. 16 is a side view (Z-Y surface) of a semiconductor module included in a semiconductor device according to embodiment (modification 2); and

FIG. 17 is a sectional view of a coupling part of the semiconductor device according to the embodiment (modification 2).

### DETAILED DESCRIPTION OF THE INVENTION

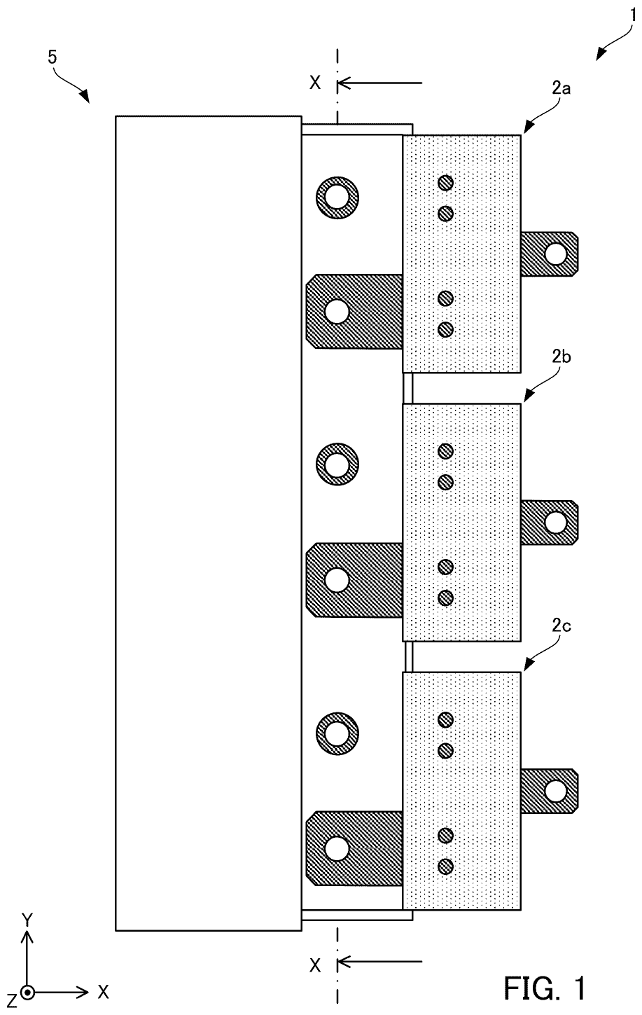

Hereinafter, an embodiment will be described with reference to the accompanying drawings. In the following description, regarding a semiconductor device 1 in FIG. 1, terms “front surface” and “top surface” each express an X-Y surface facing upward (the +Z direction). Likewise, regarding the semiconductor device 1 in FIG. 1, a term “up” expresses the upper direction (the +Z direction). Regarding the semiconductor device 1 in FIG. 1, terms “rear surface” and “bottom surface” each express an X-Y surface facing downward (the −Z direction). Likewise, regarding the semiconductor device 1 in FIG. 1, a term “down” expresses the lower direction (the −Z direction). In all the other drawings, the above terms also mean their respective directions, as appropriate. In addition, regarding the semiconductor device 1 in FIG. 1, an expression “upper level” means an upper location (the +Z direction). Likewise, regarding the semiconductor device 1 in FIG. 1, an expression “lower level” means a lower location (the −Z direction). The terms “front surface”, “top surface”, “up”, “rear surface”, “bottom surface”, “down”, and “side surface” are simply used as convenient expressions to determine relative positional relationships and do not limit the technical ideas of the embodiment. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material. In addition, an expression “approximately the same” may be used when an error between two elements is within ±10%. In addition, even when two elements are not exactly perpendicular, orthogonal, or parallel to each other, the two elements may be described as being “perpendicular”, “orthogonal”, or “parallel” to each other if the error is within ±10°.

### EMBODIMENT

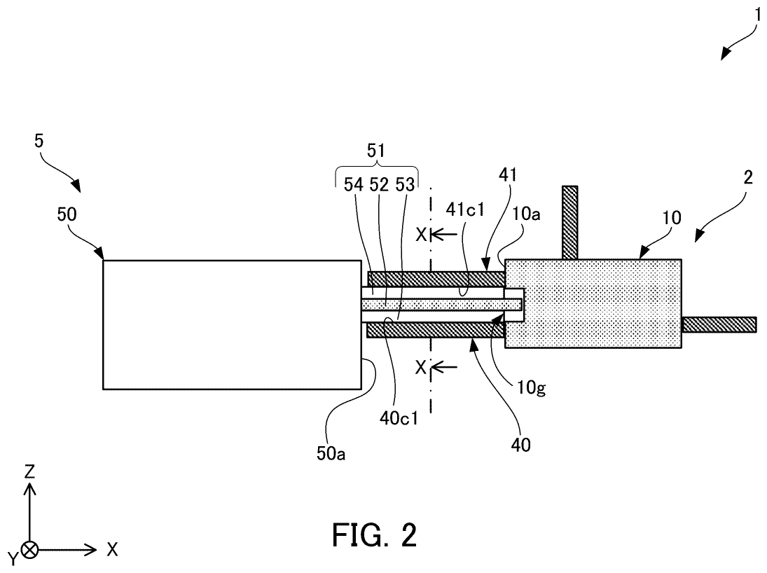

A semiconductor device according to an embodiment will be described with reference to FIGS. 1 and 2. FIG. 1 is a plan view of a semiconductor device according to an embodiment, and FIG. 2 is a side view (X-Z surface) of the semiconductor device according to the embodiment. FIG. 2 is a side view of this semiconductor device 1 in FIG. 1 seen in the +Y direction.

The semiconductor device 1 includes three semiconductor modules 2a to 2c and a capacitor 5. The semiconductor modules 2a to 2c have the same configuration and function. Hereinafter, when the semiconductor modules 2a to 2c are not distinguished from one another, any one of the semiconductor modules 2a to 2c will be referred to as a semiconductor module 2.

The individual semiconductor module 2 includes a positive terminal 40 and a negative terminal 41, which will be described below, and the capacitor 5 includes a wiring terminal 51, which will be described below. When the semiconductor modules 2 and the capacitor 5 are connected to each other, the front side and the rear side of the wiring terminal 51 are sandwiched by the positive terminals 40 and the negative terminals 41 of the semiconductor modules 2. The positive terminals 40 and the negative terminals 41 of the semiconductor modules 2 are connected to the wiring terminal 51 of the capacitor 5 by nuts and bolts. This connection will be described in detail below.

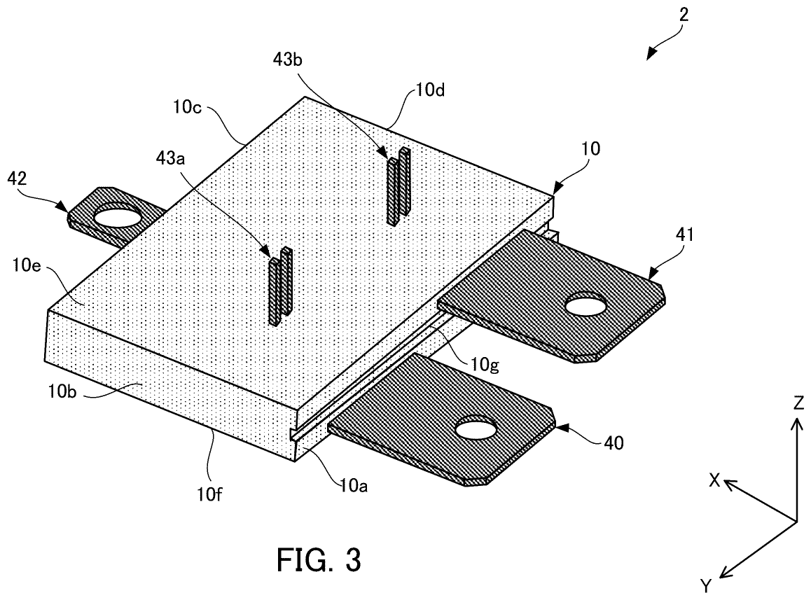

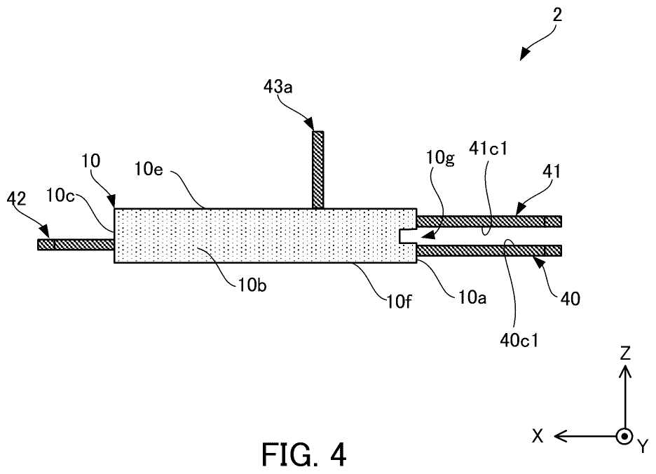

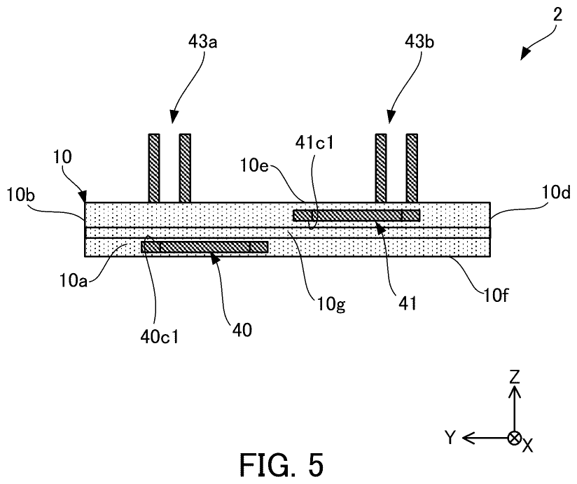

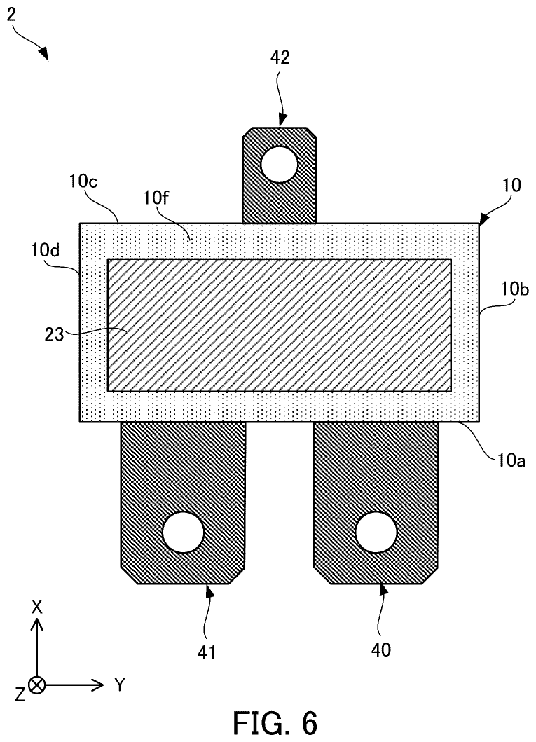

Next, the exterior of a semiconductor module 2 according to the embodiment will be described with reference to FIGS. 3 to 6. FIG. 3 is a perspective view of a semiconductor module included in the semiconductor device according to the embodiment. FIG. 4 is a side view (X-Z surface) of the semiconductor module included in the semiconductor device according to the embodiment. FIG. 5 is a side view (Z-Y surface) of the semiconductor module included in the semiconductor device according to the embodiment. FIG. 6 is a rear view of the semiconductor module included in the semiconductor device according to the embodiment.

FIG. 4 is a side view of the semiconductor module 2 in FIG. 3 seen in the −Y direction, and FIG. 5 is a side view of the semiconductor module 2 in FIG. 3 seen in the +X direction. FIG. 6 is a rear view of the semiconductor module 2 in FIG. 3 seen in the +Z direction. A side view of the semiconductor module 2 in FIG. 5 seen in the −Y direction corresponds to FIG. 4. Although a side view of the semiconductor module 2 in FIG. 3 seen in the −X direction is not illustrated, an output terminal 42 alone extends from a long side surface 10c.

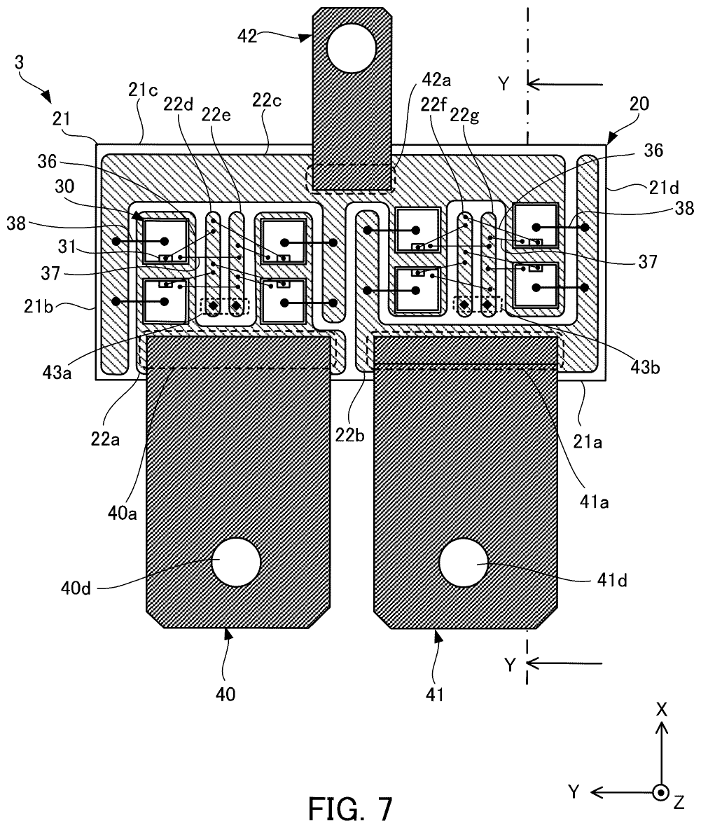

The individual semiconductor module 2 includes a semiconductor unit 3, which will be described below (FIGS. 7 to 10), and a sealing body 10 that seals the semiconductor unit 3. The sealing body 10 is an example of a fixed part, and fixes semiconductor chips 30, the positive terminal 40, and the negative terminal 41 included in the semiconductor unit 3. The sealing body 10 has a cubic shape, and has a top surface 10e having a rectangular shape in plan view and a bottom surface 10f opposite thereto. The sealing body 10 also has a long side surface 10a, a short side surface 10b, the long side surface 10c, and a short side surface 10d, which sequentially surround the four sides of each of the top surface 10e and the bottom surface 10f.

The top surface 10e and the bottom surface 10f have approximately the same shape and size. Overall, the top surface 10e and the bottom surface 10f are each an approximately flat and smooth surface. The top surface 10e and the bottom surface 10f are approximately parallel to each other. Control terminals 43a and 43b included in the semiconductor unit 3 extend vertically upward (+Z direction) from the top surface 10e. The semiconductor unit 3 includes an insulating circuit board 20, which will be described below, and the rear surface of a metal layer 23 of the insulating circuit board 20 is exposed to the outside in the bottom surface 10f. The metal layer 23 and the bottom surface 10f are approximately on the same plane.

The long side surface 10a connects a long side of the top surface 10e and a long side of the bottom surface 10f, and the long side surface 10c connects the other long side of the top surface 10e and the other long side of the bottom surface 10f. The connection individual part forms approximately a right angle. Alternatively, the individual connection part may be rounded or chamfered. The long side surface 10a is a basal surface, from which the positive terminal 40 and the negative terminal 41 included in the semiconductor unit 3 extend perpendicularly (in the −x direction). In side view (seen in the +X direction), the negative terminal 41 is located close to the top surface 10e, and the positive terminal 40 is located close to the bottom surface 10f.

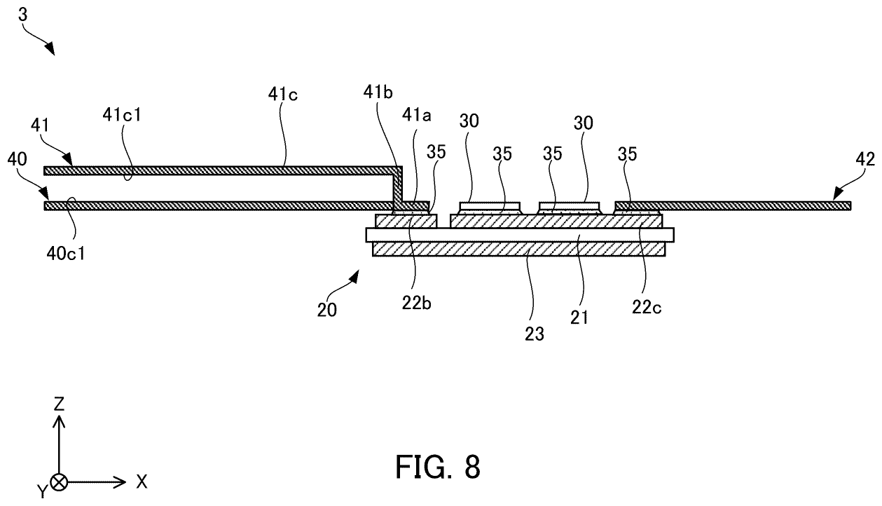

In addition, in side view (seen in +X direction), a storage groove 10g, which is a depressed area, is formed in the long side surface 10a between the positive terminal 40 and the negative terminal 41 (between the top surface 10e and the bottom surface 10f). In the long side surface 10a, the storage groove 10g is formed to extend across the width of the long side surface 10a in the ±Y directions. In addition, in plan view, the storage groove 10g is parallel to the width direction of each of the positive terminal 40 and the negative terminal 41. The depth (in the +X direction) and the width (in the ±Z directions) of the storage groove 10g may be set such that a tip of an insulating layer 52, which will be described below and which protrudes from a positive conductive layer 53 and a negative conductive layer 54 of the wiring terminal 51 of the capacitor 5, is completely insertable. The depth (in the +X direction) of the storage groove 10g may be set such that the depth does not reach a linkage area 41b (see FIG. 8) of the negative terminal 41 inside the sealing body 10. In order to maintain the insulating property of the linkage area 41b of the negative terminal 41, the distance (in the ±X directions) between a base part of the storage groove 10g and the linkage area 41b of the negative terminal 41 inside the sealing body 10 may be set to approximately 1 mm. The opening part of the storage groove 10g may be rounded or chamfered.

The output terminal 42 included in the semiconductor unit 3 extends perpendicularly (in +X direction) from a center part of the long side surface 10c. The output terminal 42 and the positive terminal 40 may be located at approximately the same height.

The short side surface 10b connects one short side of the top surface 10e and one short side of the bottom surface 10f, and the short side surface 10d connects the other short side of the top surface 10e and the other short side of the bottom surface 10f. In addition, the short side surface 10b connects one short side of the long side surface 10a and one short side of the long side surface 10c, and the short side surface 10d connects the other side of the long side surface 10a and the other side of the long side surface 10c (along the circumferential direction of the sealing body 10). The individual connection part forms approximately a right angle. Alternatively, the individual connection part may be rounded or chamfered.

The sealing body 10 is made of a material containing a thermosetting resin as its main component. Examples of the thermosetting resin include epoxy resin, phenol resin, and maleimide resin. The thermosetting resin may contain filler. Examples of the filler include silicon oxide, aluminum oxide, boron nitride, and aluminum nitride.

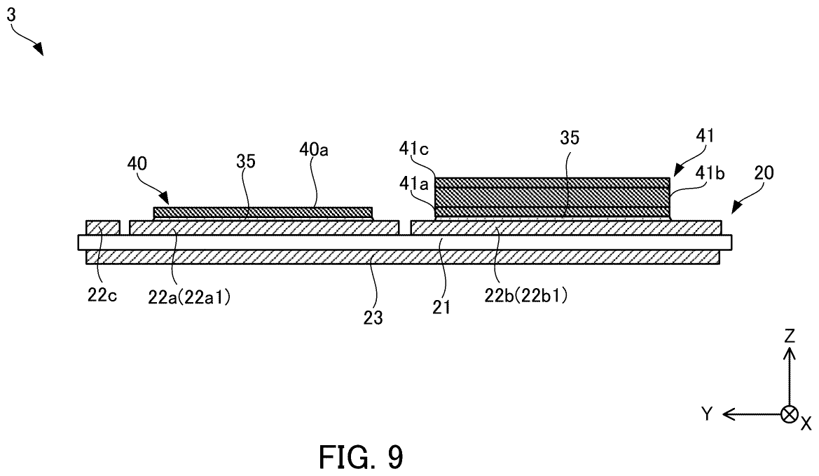

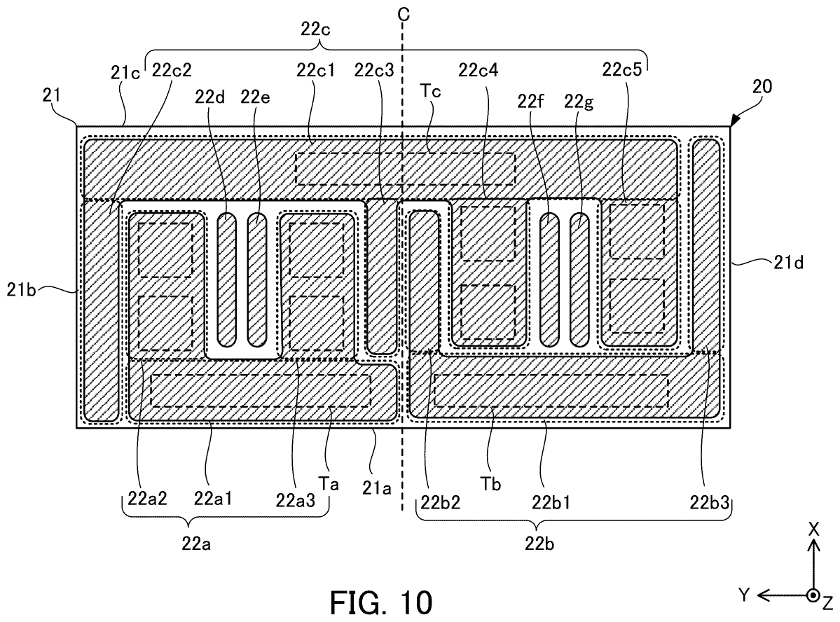

Next, a semiconductor unit 3 will be described with reference to FIGS. 7 to 10. FIG. 7 is a plan view of a semiconductor unit included in a semiconductor module according to the embodiment, and FIG. 8 is a sectional view of the semiconductor unit included in the semiconductor module according to the embodiment. FIG. 9 is a side view (Z-Y surface) of the semiconductor unit included in the semiconductor module according to the embodiment. FIG. 10 is a plan view of an insulating circuit board included in the semiconductor module according to the embodiment. FIG. 8 is a sectional view taken along a dashed-dotted line Y-Y in FIG. 7. FIG. 9 is a side view of the semiconductor unit 3 in FIG. 7 seen in the +X direction. The control terminals 43a and 43b and various kinds of wires are not illustrated in FIGS. 8 and 9.

The individual semiconductor unit 3 includes an insulating circuit board 20, semiconductor chips 30, control wires 36, sense wires 37, main current wires 38, a positive terminal 40, a negative terminal 41, an output terminal 42, and control terminals 43a and 43b.

The insulating circuit board 20 has a rectangular shape in plan view. The insulating circuit board 20 includes an insulating layer 21, a plurality of circuit pattern layers formed on the front surface of the insulating layer 21, and a metal layer 23 formed on the rear surface of the insulating layer 21. The plurality of circuit pattern layers include a positive circuit pattern layer 22a, a negative circuit pattern layer 22b, an output circuit pattern layer 22c, control circuit pattern layers 22d and 22f, and sensing circuit pattern layers 22e and 22g. Hereinafter, when these layers are not distinguished from one another, any one of these layers will be referred to as a circuit pattern layer. The outline of the plurality of circuit pattern layers and the outline of the metal layer 23 are smaller than the outline of the insulating layer 21 in plan view. The plurality of circuit pattern layers and the metal layer 23 are formed on the inner side of the insulating layer 21. The shape, number, and size of the plurality of circuit pattern layers are only examples.

The insulating layer 21 has a rectangular shape in plan view. The insulating layer 21 may have chamfered corners. For example, corners of the insulating layer 21 may be chamfered or rounded. The insulating layer 21 has a long side surface 21a, a short side surface 21b, a long side surface 21c, and a short side surface 21d, which are outer circumferential sides in four directions. The insulating layer 21 is made of a ceramic material having an excellent thermal conductivity. For example, the ceramic material contains aluminum oxide, aluminum nitride, or silicon nitride as its main component.

The metal layer 23 has a rectangular shape in plan view. For example, the metal layer 23 may have chamfered or rounded corners. The metal layer 23 is smaller than the insulating layer 21 and is formed on the rear surface of the insulating layer 21, excepting the edge parts of the insulating layer 21. The metal layer 23 is made of a material containing a metal material having an excellent thermal conductivity as its main component. The metal material is, for example, copper, aluminum, or an alloy containing at least one of these kinds of elements. To improve the corrosion resistance of the metal plate, plating may be performed. The material used for this plating is, for example, nickel, a nickel-phosphorus alloy, or a nickel-boron alloy.

As described above, the plurality of circuit pattern layers include the positive circuit pattern layer 22a, the negative circuit pattern layer 22b, the output circuit pattern layer 22c, the control circuit pattern layers 22d and 22f, and the sensing circuit pattern layers 22e and 22g. The plurality of circuit pattern layers are formed on the front surface of the insulating layer 21, excepting the edge parts of the insulating layer 21. Preferably, in plan view, the end parts of the plurality of circuit pattern layers, the end parts facing the outer circumference of the insulating layer 21, overlap the end parts of the metal layer 23, the end parts facing the outer circumference of the insulating layer 21.

The plurality of circuit pattern layers are made of a metal material having an excellent electrical conductivity. The metal material is, for example, copper, aluminum, or an alloy containing at least one of these kinds of elements. The surface of each of the plurality of circuit pattern layers may be plated to improve its corrosion resistance. The material used for this plating is, for example, nickel, a nickel-phosphorus alloy, or a nickel-boron alloy.

The positive circuit pattern layer 22a included in the plurality of circuit pattern layers has an F shape in plan view, and is formed to face the long side surface 21a of the insulating layer 21. The positive circuit pattern layer 22a includes a terminal area 22a1 and chip areas 22a2 and 22a3.

The terminal area 22a1 has a rectangular shape in plan view. On the front surface of the insulating layer 21, the terminal area 22a1 is formed to extend in parallel to the long side surface 21a (longitudinal direction). A-Y direction end part of the terminal area 22a1 is away from a center line C on the front surface of the insulating layer 21 toward the short side surface 21b by a predetermined distance. The center line C goes through the center of each of the long side surfaces 21a and 21c and is parallel to the short side surfaces 21b and 21d. There is a gap between a +Y direction end part of the terminal area 22a1 and the short side surface 21b. The terminal area 22a1 faces the long side surface 21a. A dashed area (a placement area Ta) indicated inside the terminal area 22a1 is a part to which the positive terminal 40 is bonded.

The chip area 22a2 has a rectangular shape in plan view. The chip area 22a2 extends from the +Y direction end part of the terminal area 22a1 toward the long side surface 21c in parallel to the short side surfaces 21b and 21d (lateral direction). There is a gap between a +X direction end part of the chip area 22a2 and the long side surface 21c. A +Y direction end part of the chip area 22a2 and the +Y direction end part of the terminal area 22a1 are on the same plane. Two dashed areas indicated inside the chip area 22a2 are parts to which semiconductor chips 30 (first semiconductor chips) are bonded.

The chip area 22a3 has a rectangular shape in plan view. The chip area 22a3 is connected to a part of the terminal area 22a1, the part being away from the −Y direction end part of the terminal area 22a1 in the +Y direction by a predetermined distance, and extends toward the long side surface 21c in parallel to the short side surfaces 21b and 21d. There is a gap between a +X direction end part of the chip area 22a3 and the long side surface 21c. The +X direction end parts of the chip areas 22a2 and 22a3 are on the same plane. In addition, there is a gap between a −Y direction end part of the chip area 22a3 and the center line C. There is a gap between a-Y direction end part of the chip area 22a2 and a +Y direction end part of the chip area 22a3. Two dashed areas indicated inside the chip area 22a3 are parts to which semiconductor chips 30 (first semiconductor chips) are bonded. The chip area 22a3 and the chip area 22a2 have approximately the same ±Y direction width.

The negative circuit pattern layer 22b included in the plurality of circuit pattern layers has a J shape in plan view, and is formed to face the long side surface 21a of the insulating layer 21. The negative circuit pattern layer 22b includes a terminal area 22b1 and wiring areas 22b2 and 22b3.

The terminal area 22b1 has a rectangular shape in plan view. On the front surface of the insulating layer 21, the terminal area 22b1 is formed to extend in parallel to the long side surface 21a (longitudinal direction). A +Y direction end part of the terminal area 22b1 is away from the center line C on the front surface of the insulating layer 21 toward the short side surface 21d by a predetermined distance. The +Y direction end part of the terminal area 22b1 and the −Y direction end part of the terminal area 22a1 are symmetrical with respect to the center line C. The terminal area 22b1 faces the long side surface 21a. A dashed area (a placement area Tb) indicated inside the terminal area 22b1 is a part to which the negative terminal 41 is bonded.

The wiring area 22b2 has a rectangular shape in plan view. The wiring area 22b2 extends from a +Y direction end part of the terminal area 22b1 toward the long side surface 21c in parallel to the short side surfaces 21b and 21d (lateral direction). There is a gap between a +X direction end part of the wiring area 22b2 and the long side surface 21c. A +Y direction end part of the wiring area 22b2 and the +Y direction end part of the terminal area 22b1 are on the same plane.

The wiring area 22b3 has a rectangular shape in plan view. The wiring area 22b3 extends from a −Y direction end part of the terminal area 22b1 toward the long side surface 21c in parallel to the short side surfaces 21b and 21d (lateral direction). A +X direction end part of the wiring area 22b3 is formed with a gap from an edge part of the long side surface 21c. A −Y direction end part of the wiring area 22b3 faces the short side surface 21d. The −Y direction end part of the wiring area 22b3 and the −Y direction end part of the terminal area 22b1 are on the same plane. The wiring area 22b3 and the wiring area 22b2 have approximately the same ±Y direction width.

The output circuit pattern layer 22c included in the plurality of circuit pattern layers has a comb-like shape in plan view, and is formed to face the long side surface 21c of the insulating layer 21. The output circuit pattern layer 22c includes a terminal area 22c1 wiring areas 22c2 and 22c3, and chip areas 22c4 and 22c5.

The terminal area 22c1 has a rectangular shape in plan view. On the front surface of the insulating layer 21, the terminal area 22c1 is formed to extend in parallel to the long side surface 21c (longitudinal direction). A +Y direction end part of the terminal area 22c1 faces the short side surface 21b of the front surface of the insulating layer 21. In addition, a-Y direction end part of the terminal area 22c1 is formed with a gap from the short side surface 21d. The terminal area 22c1 also faces the long side surface 21c. A dashed area (a placement area Tc) indicated inside the terminal area 22c1 is a part to which the output terminal 42 is bonded.

The wiring area 22c2 has a rectangular shape in plan view. The wiring area 22c2 extends from the +Y direction end part of the terminal area 22c1 toward the long side surface 21a in parallel to the short side surfaces 21b and 21d (lateral direction). A −X direction end part of the wiring area 22c2 faces the long side surface 21a. A +Y direction end part of the wiring area 22c2 and the +Y direction end part of the terminal area 22c1 are on the same plane.

The wiring area 22c3 has a rectangular shape in plan view. The wiring area 22c3 extends from the terminal area 22c1 toward the long side surface 21a between the chip area 22a3 and the wiring area 22b2 in parallel to the short side surfaces 21b and 21d (lateral direction). A −X direction end part of the wiring area 22c3 faces the terminal area 22a1.

The ±Y direction width of the wiring area 22c3 corresponds to the interval between the chip area 22a3 and the wiring area 22b2, and is approximately the same as the ±Y direction width of the wiring area 22c2.

The chip area 22c4 has a rectangular shape in plan view. The chip area 22c4 extends from the terminal area 22c1 toward the long side surface 21a in parallel to the short side surfaces 21b and 21d (lateral direction) between the wiring area 22b2 and the control circuit pattern layer 22f, which will be described below. A −X direction end part of the chip area 22c4 faces the terminal area 22b1. Two dashed areas indicated inside the chip area 22c4 are parts to which semiconductor chips 30 (second semiconductor chips) are bonded.

The chip area 22c5 has a rectangular shape in plan view. The chip area 22c5 extends from the −Y direction end part of the terminal area 22c1 toward the long side surface 21a in parallel to the short side surfaces 21b and 21d (lateral direction) between the wiring area 22b3 and the sensing circuit pattern layer 22g, which will be described below. A −X direction end part of the chip area 22c5 faces the terminal area 22b1. The −X direction end parts of the chip areas 22c4 and 22c5 and the wiring area 22c3 are on the same plane. In addition, a −-Y direction end part of the chip area 22c5 and the −Y direction end part of the terminal area 22c1 are on the same plane. Two dashed areas indicated inside the chip area 22c5 are parts to which semiconductor chips 30 (second semiconductor chips) are bonded. The chip area 22c5 and the chip area 22c4 have approximately the same +Y direction width. In addition, the width of the gap between a +Y direction end part of the chip area 22c5 and a −Y direction end part of the chip area 22c4 is approximately the same as the ±Y direction width of each of the chip areas 22c4 and 22c5.

The control circuit pattern layer 22d and the sensing circuit pattern layer 22e included in the plurality of circuit pattern layers each have a rectangular shape in plan view, and are each formed in an area surrounded by the positive circuit pattern layer 22a and the terminal area 22c1 of the output circuit pattern layer 22c in parallel to the short side surfaces 21b and 21d (lateral direction). The control circuit pattern layer 22d and the sensing circuit pattern layer 22e each have a ±Y direction width shorter than that of the wiring area 22c2.

The control circuit pattern layer 22f and the sensing circuit pattern layer 22g included in the plurality of circuit pattern layers each have a rectangular shape in plan view, and are each formed in an area surrounded by the terminal area 22b1 of the negative circuit pattern layer 22b and the terminal area 22c1 and the chip areas 22c4 and 22c5 of the output circuit pattern layer 22c in parallel to the short side surfaces 21b and 21d (lateral direction). The control circuit pattern layer 22f and the sensing circuit pattern layer 22g each have a ±Y direction width shorter than that of the wiring area 22c2.

For example, a direct copper bonding (DCB) substrate or an active metal brazed (AMB) substrate may be used as the insulating circuit board 20 having the above-described construction. The insulating circuit board 20 releases the heat generated by the semiconductor chips 30, by transferring the heat to the rear surface of the insulating circuit board 20 via the positive circuit pattern layer 22a, the negative circuit pattern layer 22b, the insulating layer 21, and the metal layer 23.

The semiconductor chips 30 (first and second semiconductor chips) are each a power device made of silicon carbide. For example, the power device is a power metal-oxide-semiconductor field-effect transistor (MOSFET). The body diode of the power MOSFET functions as a freewheeling diode (FWD). The individual semiconductor chip 30 has a drain electrode as an input electrode (first or third electrode) on its rear surface and has a gate electrode as a control electrode 31 and a source electrode as an output electrode (second or fourth electrode) on its front surface.

Alternatively, the individual semiconductor chip 30 may be a power device made of silicon. The power device in this case is, for example, a reverse-conducting (RC) insulated gate bipolar transistor (IGBT). The RC-IGBT is constituted by forming a circuit, in which an IGBT serving as a switching element and an FWD serving as a diode element are connected in anti-parallel to each other, on one chip. For example, this semiconductor chip 30 has a collector electrode as an input electrode (first electrode) on its rear surface and has a gate electrode as a control electrode and an emitter electrode as an output electrode (second electrode) on its front surface.

In the present embodiment, a plurality of semiconductor chips 30 are disposed on the positive circuit pattern layer 22a and the output circuit pattern layer 22c via a bonding member 35 described above. The present embodiment illustrates an example case in which two semiconductor chips 30 are disposed in each of the chip areas 22a2 and 22a3 of the positive circuit pattern layer 22a and in each of the chip areas 22c4 and 22c5 of the output circuit pattern layer 22c in parallel to the short side surfaces 21b and 21d. In addition, in the present embodiment, the control electrodes 31 of the two semiconductor chips 30 disposed in each of the chip areas 22a2 and 22a3 of the positive circuit pattern layer 22a and the chip areas 22c4 and 22c5 of the output circuit pattern layer 22c are disposed to face each other.

The positive terminal 40 (first terminal), the negative terminal 41 (second terminal), the output terminal 42, and the control terminals 43a and 43b are each made of a metal material having an excellent electrical conductivity. The metal material is, for example, copper, a copper alloy, aluminum, or an aluminum alloy. Plating may be performed to improve the corrosion resistance of the metal plates of the positive terminal 40, the negative terminal 41, the output terminal 42, and the control terminals 43a and 43b. The material used for this plating is, for example, nickel, a nickel-phosphorus alloy, or a nickel-boron alloy.

The positive terminal 40 has a flat plate shape. A positive bonding area 40a, which is an inner end part of the positive terminal 40, is bonded to the placement area Ta in the terminal area 22a1 of the positive circuit pattern layer 22a via a bonding member 35. That is, the positive terminal 40 is electrically connected to the input electrodes on the rear surfaces of the corresponding semiconductor chips 30. An outer end part (a first end part) of the positive terminal 40 extends perpendicularly (-X direction) from the terminal area 22a1 of the positive circuit pattern layer 22a. Corners of the outer end part of the positive terminal 40 may be rounded or chamfered. A contact surface 40c1 (first contact surface) on the front surface of the outer end part of the positive terminal 40 comes in contact with the positive conductive layer 53 included in the wiring terminal 51 of the capacitor 5, which will be described below. A fastening hole 40d, which passes through the positive terminal 40, may be formed in the outer end part of the positive terminal 40. A bus-bar may be attached by using the fastening hole 40d. Overall, the positive terminal 40 has an approximately uniform thickness and uniform width (in the ±Y directions in FIG. 7). The thickness of the positive terminal 40 is, for example, between 0.4 mm and 0.6 mm, inclusive. The-X direction length of the positive terminal 40 from the long side surface 10a of the sealing body 10 is, for example, between 20 mm and 30 mm, inclusive.

The negative terminal 41 includes a negative bonding area 41a, a linkage area 41b, and a wiring area 41c. These negative bonding area 41a, linkage area 41b, and wiring area 41c each have a flat plate shape. Overall, the negative terminal 41 has an approximately uniform thickness and uniform width (in the ±Y directions in FIG. 7). In plan view, the width direction (second width direction) (±Y direction) of the negative terminal 41 is parallel to the width direction (first width direction) (±Y direction) of the positive terminal 40. Thus, the width direction of the negative terminal 41 and the positive terminal 40 is parallel to the long side surface 10a of the sealing body 10. In addition, the width direction of the negative terminal 41 is located differently from the width direction of the positive terminal 40 (±Y directions). The negative bonding area 41a, which is an inner end part of the negative terminal 41, is boned to the placement area Tb in the terminal area 22b1 of the negative circuit pattern layer 22b via a bonding member 35. The linkage area 41b is connected to an end part (in the −X direction in FIG. 7) of the negative bonding area 41a and extends vertically upward (in the +Z direction). The wiring area 41c connects to the linkage area 41b and extends perpendicularly (−X direction) from the terminal area 22b1 of the negative circuit pattern layer 22b. Thus, the wiring area 41c of the negative terminal 41 is away from the front surface of the insulating circuit board 20 in the +Z direction by the height of the linkage area 41b. In addition, corners of an outer end part of the wiring area 41c of the negative terminal 41 may be rounded or chamfered. A contact surface 41c1 (second contact surface) on the rear surface of the outer end part of the negative terminal 41 (wiring area 41c) comes in contact with the negative conductive layer 54 included in the wiring terminal 51 of the capacitor 5, which will be described below. In side view, the contact surface 41c1 of the negative terminal 41 is in parallel to the contact surface 40c1 of the positive terminal 40. A fastening hole 41d, which passes through the negative terminal 41, may be formed in the outer end part of the negative terminal 41. The wiring terminal 51 of the capacitor 5, which will be described below, may be attached by using the fastening hole 41d. The thickness of the negative terminal 41 is, for example, 0.4 mm and 0.6 mm, inclusive. In addition, the-X direction length of the negative terminal 41 from the long side surface 10a of the sealing body 10 is, for example, between 20 mm and 30 mm, inclusive.

The output terminal 42 has a flat plate shape. An output bonding area 42a, which is an inner end part of the output terminal 42, is bonded to the placement area Tc in the terminal area 22c1 of the output circuit pattern layer 22c via a bonding member 35. An outer end part of the output terminal 42 extends perpendicularly (+X direction) from the terminal area 22c1 of the output circuit pattern layer 22c. Corners of the outer end part of the output terminal 42 may be rounded or chamfered. A through-hole may be formed in the outer end part of the output terminal 42. A bus bar may be attached by using the through-hole. In addition, overall, the output terminal 42 has an approximately uniform thickness and uniform width (±Y directions in FIG. 7).

Each of the control terminals 43a and 43b has a columnar shape whose cross section may be a polygonal shape, a circular shape, or an elliptic shape. The lower end part of one of the control terminals 43a is bonded to an end part of the control circuit pattern layer 22d, the end part being located in the direction of the long side surface 21a, via a bonding member 35 (not illustrated). The lower end part of the other control terminal 43a is bonded to an end part of the sensing circuit pattern layer 22e, the end part being located in the direction of the long side surface 21a, via a bonding member 35 (not illustrated). The upper end part of each of the control terminals 43a extends vertically upward (+Z direction) from the corresponding one of the control circuit pattern layer 22d and the sensing circuit pattern layer 22e. The lower end part of one of the control terminals 43b is bonded to an end part of the control circuit pattern layer 22f, the end part being located in the direction of the long side surface 21a, via a bonding member 35 (not illustrated). The lower end part of the other control terminal 43b is bonded to an end part of the sensing circuit pattern layer 22g, the end part being located in the direction of the long side surface 21a, via a bonding member 35 (not illustrated). The upper end part of each of the control terminals 43b extends vertically upward (+Z direction) from the corresponding one of the control circuit pattern layer 22f and the sensing circuit pattern layer 22g.

The control wires 36, the sense wires 37, and the main current wires 38 are each made of a material having an excellent electrical conductivity as its main component. The material is, for example, gold, copper, aluminum, or an alloy containing at least one of these kinds of elements. The control wires 36 and the sense wires 37 may have a diameter smaller than that of the main current wires 38.

Each of the control wires 36 (located in the +Y direction in FIG. 7) directly connects the control electrode 31 of a semiconductor chip 30 and the control circuit pattern layer 22d. Each of the control wires 36 (located in the −Y direction in FIG. 7) directly connects the control electrode 31 of a semiconductor chip 30 and the control circuit pattern layer 22f.

Each of the sense wires 37 (located in the +Y direction in FIG. 7) directly connects the output electrode of a semiconductor chip 30 and the sensing circuit pattern layer 22e. Each of the sense wires 37 (located in the −Y direction in FIG. 7) directly connects the output electrode of a semiconductor chip 30 and the sensing circuit pattern layer 22g.

Each of the main current wires 38 (located in the +Y direction in FIG. 7) directly connects the output electrode of a semiconductor chip 30 and the wiring area 22c2 or 22c3 of the output circuit pattern layer 22c. Each of the main current wires 38 (located in the −Y direction in FIG. 7) directly connects the output electrode of a semiconductor chip 30 and the wiring area 22b2 or 22b3 of the negative circuit pattern layer 22b. The main current wires 38 extend in parallel to the long side surfaces 21a and 21c.

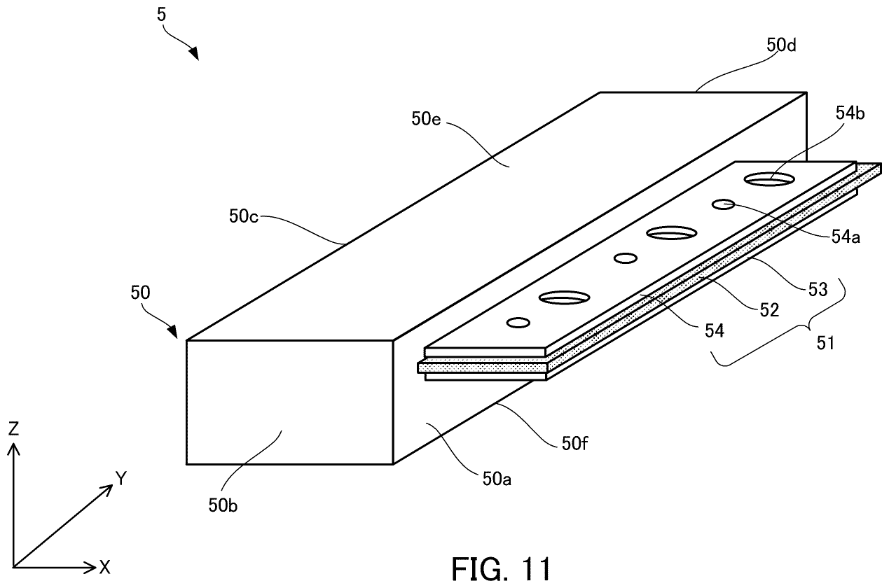

Next, the capacitor 5 will be described with reference to FIG. 11. FIG. 11 is a perspective view of the capacitor included in the semiconductor device according to the embodiment. The capacitor 5 includes a housing 50 and the wiring terminal 51.

The housing 50 is the main body of the capacitor. The housing 50 has a top surface 50e, a bottom surface 50f, a long side surface 50a, a short side surface 50b, a long side surface 50c, and a short side surface 50d. The top surface 50e and the bottom surface 50f have the same shape and size, and each have a rectangular shape in plan view. The long side surface 50a, the short side surface 50b, the long side surface 50c, and the short side surface 50d sequentially surround the top surface 50e and the bottom surface 50f in four directions. The long side surface 50a connects to one long side of the top surface 50e and one long side of the bottom surface 50f, and the long side surface 50c connects to the other long side of the top surface 50e and the other long side of the bottom surface 50f. The short side surface 50b connects to one short side of the top surface 50e and one short side of the bottom surface 50f, and the short side surface 50d connects to the other short side of the top surface 50e and the other short side of the bottom surface 50f. For example, the housing 50 is made of epoxy resin. While not illustrated, a plurality of capacitor components having N and P poles are stored inside the housing 50.

The wiring terminal 51 includes the insulating layer 52, the positive conductive layer 53 (first conductive layer), and the negative conductive layer 54 (second conductive The insulating layer 52 is made of an insulating layer). material having an insulating property. For example, the insulating material contains, its as main component, insulating paper based on fully aromatic polyamide polymer or fluorine or polyimide resin material. The insulating layer 52 is obtained by forming the insulating material into a sheet. The insulating layer 52 extends outwardly from the long side surface 50a of the housing 50. As will be described below, the insulating layer 52 is sandwiched by the positive conductive layer 53 and the negative conductive layer 54, and consequently maintains the insulation between the positive conductive layer 53 and the negative conductive layer 54. The insulating layer 52 also maintains the insulation between the positive conductive layer 53 and the negative conductive layer 54 inside the housing 50. The insulating layer 52 has holes at parts facing positive fastening holes 53a, negative opening holes 53b, negative fastening holes 54a, and positive opening holes 54b, which will be described below.

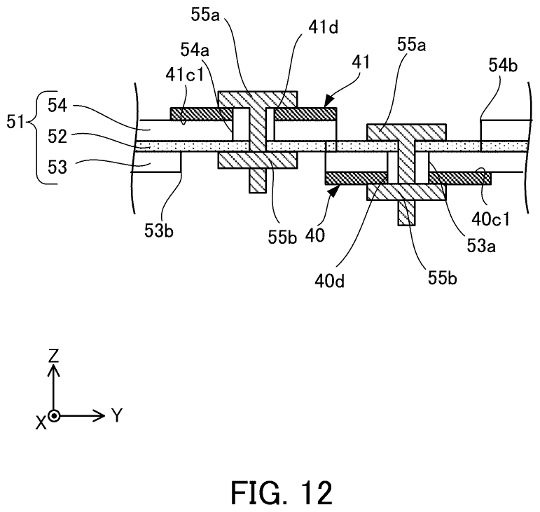

The positive conductive layer 53 is electrically connected to each of the P poles of the plurality of capacitor components inside the housing 50, and extends outwardly from the long side surface 50a of the housing 50. The outwardly extending part of the positive conductive layer 53 has a flat plate shape and is formed on the rear surface of the insulating layer 52. The positive conductive layer 53 has the positive fastening holes 53a and the negative opening holes 53b (see FIG. 12). A positive fastening hole 53a and a negative opening hole 53b are formed as a pair, and the number of pairs formed corresponds to the number of semiconductor modules 2 attached to the wiring terminal 51. The positive terminal 40 of each semiconductor module 2 is fastened to a positive fastening hole 53a by a bolt. The individual negative opening hole 53b has a diameter sufficiently larger than that of the individual positive fastening hole 53a. A bolt for fastening the negative terminal 41 of a semiconductor module 2 is inserted into a negative opening hole 53b such that the bolt will not come in contact with the positive conductive layer 53.

The negative conductive layer 54 is electrically connected to each of the N poles of the plurality of capacitor components inside the housing 50, and extends outwardly from the long side surface 50a of the housing 50. The outwardly extending part of the part negative conductive layer 54 has a flat plate shape and is formed on the front surface of the insulating layer 52. The outwardly extending part of the negative conductive layer 54 and the outwardly extending part of the positive conductive layer 53 have the same shape and size. The negative conductive layer 54 has the negative fastening holes 54a and the positive opening holes 54b (see FIG. 12). A negative fastening hole 54a and a positive opening hole 54b are formed as a pair, and the number of pairs formed corresponds to the number of semiconductor modules 2 attached to the wiring terminal 51. The negative terminal 41 of each semiconductor module 2 is fastened to a negative fastening hole 54a by a bolt. The individual positive opening hole 54b has a diameter sufficiently larger than that of the individual negative fastening hole 54a. A bolt for fastening the positive terminal 40 of a semiconductor module 2 is inserted into a positive opening hole 54b such that the bolt will not come into contact with the negative conductive layer 54.

With this wiring terminal 51, in plan view, a positive fastening hole 53a corresponds to a positive opening hole 54b, and a negative fastening hole 54a corresponds to a negative opening hole 53b. At least a part of the insulating layer 52, the part being outside the long side surface 50a of the housing 50, is larger than the positive conductive layer 53 and the negative conductive layer 54. Thus, outer edges (peripheral sides) of the insulating layer 52 sandwiched by the positive conductive layer 53 and the negative conductive layer 54 protrude from outer edges (peripheral sides) of the positive conductive layer 53 and the negative conductive layer 54. The protrusion length of the insulating layer 52 is, for example, between 1.0 mm and 1.4 mm, inclusive. Thus, because the insulation distance between the positive conductive layer 53 and the negative conductive layer 54 is maintained, the insulation between the positive conductive layer 53 and the negative conductive layer 54 is maintained.

Next, coupling of the individual semiconductor module 2 and the capacitor 5 will be described with reference to FIGS. 1, 2, and 12. FIG. 12 is a sectional view of a coupling part of the semiconductor device according to the embodiment. FIG. 12 is a sectional view taken along a dashed-dotted line X-X in FIGS. 1 and 2 when the individual semiconductor module 2 and the capacitor 5 are coupled to each other by bolts 55a and nuts 55b. Herein, the bolts 55a and nuts 55b are each made of an electrically conductive metal material, for example.

First, the long side surfaces 10a of a plurality of (herein, for example, three) semiconductor modules 2 are set to face the long side surface 50a of the capacitor 5. Next, the plurality of semiconductor modules 2 are moved toward the capacitor 5. As a result, the wiring terminal 51 of the capacitor 5 is sandwiched by the positive terminals 40 and the negative terminals 41 of the plurality of semiconductor modules 2, as illustrated in FIGS. 1 and 2. That is, the positive terminals 40 of the plurality of semiconductor modules 2 come in contact with the rear surface of the positive conductive layer 53 of the wiring terminal 51. At this point of time, a tip of the positive conductive layer 53 of the wiring terminal 51 comes in contact with the long side surfaces 10a of the semiconductor modules 2. The negative terminals 41 of the plurality of semiconductor modules 2 come in contact with the front surface of the negative conductive layer 54 of the wiring terminal 51. At this point of time, a tip of the negative conductive layer 54 of the wiring terminal 51 comes in contact with the long side surfaces 10a of the semiconductor modules 2. In addition, a tip of the insulating layer 52 is inserted into (stored in) the storage grooves 10g in the long side surfaces 10a of the semiconductor modules 2.

After the wiring terminal 51 of the capacitor 5 is attached between the positive terminals 40 and the negative terminals 41 of the semiconductor modules 2, the bolts 55a are inserted into the fastening holes 41d in the negative terminals 41 and the negative fastening holes 54a in the negative conductive layer 54 from the front sides of the negative terminals 41, as illustrated in FIG. 12. Each bolt 55a has its lower end part exposed to the outside in a negative opening hole 53b in the positive conductive layer 53, and a nut 55b is fastened to the lower end part inside the corresponding negative opening hole 53b in the positive conductive layer 53. Since the individual negative opening hole 53b in the positive conductive layer 53 has a diameter sufficiently larger than that of the individual nut 55b, these bolts 55a and nuts 55b do not come in contact with the positive conductive layer 53, and the insulation is consequently maintained. That is, the insulation between the negative terminals 41 and the positive conductive layer 53 is maintained.

Similarly, bolts 55a are inserted into the positive fastening holes 53a in the positive conductive layer 53 and the fastening holes 40d in the positive terminals 40 from the positive opening holes 54b in the negative conductive layer 54. Each bolt 55a has its lower end part exposed to the outside in the fastening hole 40d in a positive terminal 40, and a nut 55b is fastened to the lower end part. Since the individual positive opening holes 54b in the negative conductive layer 54 has a diameter sufficiently larger than that of the individual bolt 55a, these bolts 55a do not come in contact with the negative conductive layer 54, and the insulation is consequently maintained. That is, the insulation between the positive terminals 40 and the negative conductive layer 54 is maintained.

The plurality of semiconductor modules 2 and the capacitor 5 are mechanically and electrically coupled to each other as described above, and the semiconductor device 1 is consequently constructed.

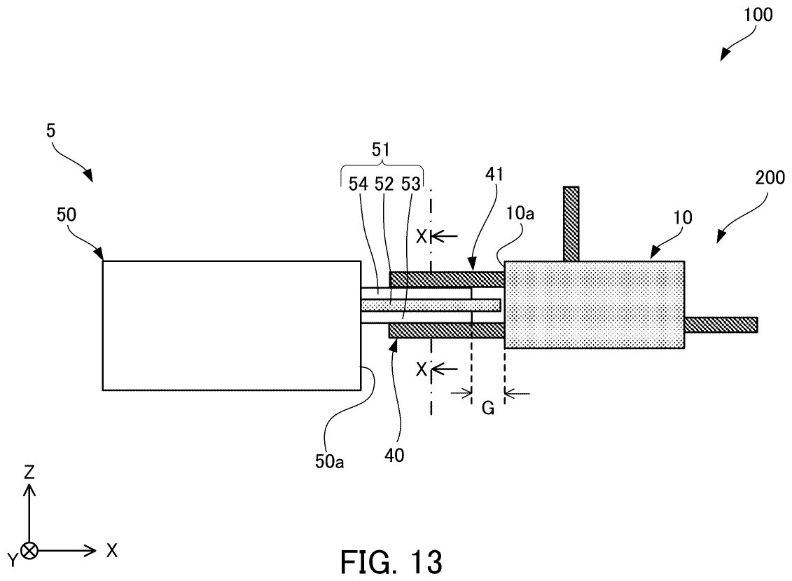

Next, a reference example, which will be compared with the semiconductor device 1 according to the embodiment, will be described. An individual semiconductor module included in a semiconductor device according to the reference example does not have the storage groove 10g, which is included in the individual semiconductor module 2 described above. This semiconductor device according to the reference example will be described with reference to FIG. 13. FIG. 13 is a side view (X-Z surface) of the semiconductor device according to the reference example. FIG. 13 illustrating this semiconductor device 100 according to the reference example corresponds to FIG. 2.

The semiconductor device 100 includes a plurality of semiconductor modules 200 and a capacitor 5. The capacitor 5 is the same as the capacitor 5 according to the embodiment. The individual semiconductor module 200 does not have the storage groove 10g, which is formed in the long side surface 10a of the individual semiconductor module 2 according to the embodiment. The individual semiconductor module 200 has a generally flat long side surface 10a. The semiconductor modules 200 have the same construction as that of the semiconductor modules 2, except the long side surfaces 10a.

A wiring terminal 51 of the capacitor 5 is attached to positive terminals 40 and negative terminals 41 of the plurality of semiconductor modules 200, as illustrated in FIG. 13 (also see FIG. 1). In this case, the (+X direction) tip of the wiring terminal 51 (an insulating layer 52) comes in contact with the long side surface 10a of the individual semiconductor module 200. In addition, a gap G is formed between the (+X direction) tip of a positive conductive layer 53 and a negative conductive layer 54 and the long side surface 10a of the individual semiconductor module 200.

The inductance component of the semiconductor device 100 depends on the length of the wiring terminal 51 of the capacitor 5 and the length of the positive terminal 40 and the negative terminal 41 of the individual semiconductor module 200. The inductance of the wiring terminal 51 of the capacitor 5 is reduced by sandwiching the insulating layer 52 between the positive conductive layer 53 and the negative conductive layer 54 (by carrying out lamination). In addition, it is desirable to carry out the lamination including not only the wiring terminal 51 but also the positive terminals 40 and the negative terminals 41 of the semiconductor modules 200. In this way, the wiring terminal 51 and the positive terminals 40 and the negative terminals 41 have a positional relationship in which currents that flow in two directions based on switching overlap each other. As a result, because the magnetic fields are offset, the inductance is reduced.

However, because of the gap G, the wiring terminal 51 and the positive terminals 40 and the negative terminals 41 of the semiconductor modules 200 do not completely overlap one another. Thus, the inductance is not reduced at the gap G.

In contrast, the semiconductor device 1 according to the embodiment includes semiconductor modules 2 and a capacitor 5. The capacitor 5 includes a wiring terminal 51 including an insulating layer 52, a positive conductive layer 53 formed on one main surface of the insulating layer 52, and a negative conductive layer 54 formed on the other main surface of the insulating layer 52. The insulating layer 52 has an insulating peripheral side that extends more outwardly than a conductive peripheral side of each of the positive conductive layer 53 and the negative conductive layer 54.

The individual semiconductor module 2 includes: a semiconductor chip 30 having an output electrode and an input electrode; a negative terminal 41 which has a contact surface 41c1 that is in contact with the negative conductive layer 54 of the wiring terminal 51 and which is electrically connected to the output electrode of the semiconductor chip 30; and a positive terminal 40 which has a contact surface 40c1 that is away from and parallel to the negative terminal 41 and that is electrically connected to the positive conductive layer 53 of the wiring terminal 51 and which is electrically connected to the input electrode of the semiconductor chip 30. The semiconductor module 2 includes a sealing body 10 having a long side surface 10a which faces the wiring terminal 51 and from which the positive terminal 40 and the negative terminal 41 extend outwardly in the same direction, fixing the semiconductor chip 30, the positive terminal 40, and the negative terminal 41, and having a storage groove 10g in the long side surface 10a between the positive terminal 40 and the negative terminal 41, a tip of the insulating layer 52 of the wiring terminal 51 being inserted into the storage groove 10g. In the case of the semiconductor device 1, because the tip of the insulating layer 52 of the wiring terminal 51 of the capacitor 5 is inserted into the storage groove 10g in the long side surface 10a of the individual semiconductor module 2, it is possible to increase the area where the positive terminal 40 and the negative terminal 41 of the individual semiconductor module 2 overlap the wiring terminal 51 of the capacitor 5. Thus, the inductance is less than that of the semiconductor device 100 according to the reference example.

As the tip of the insulating layer 52 of the wiring terminal 51 is inserted more deeply into the storage groove 10g in the long side surface 10a of the individual semiconductor module 2, the gap G according to the reference example is reduced further, and the inductance is reduced more. That is, it is possible to reduce the inductance by inserting the tip of the insulating layer 52 of the wiring terminal 51 into the storage groove 10g in the long side surface 10a of the individual semiconductor module 2 even if it is only a little and by reducing the gap G. Thus, it is preferable that the depth of the storage groove 10g in the long side surface 10a of the individual semiconductor module 2 be set such that the gap G will not be formed, that is, such that the entire tip of the insulating layer 52 protruding from the positive conductive layer 53 and the negative conductive layer 54 of the wiring terminal 51 of the capacitor 5 will be inserted into the storage groove 10g.

### Modification 1

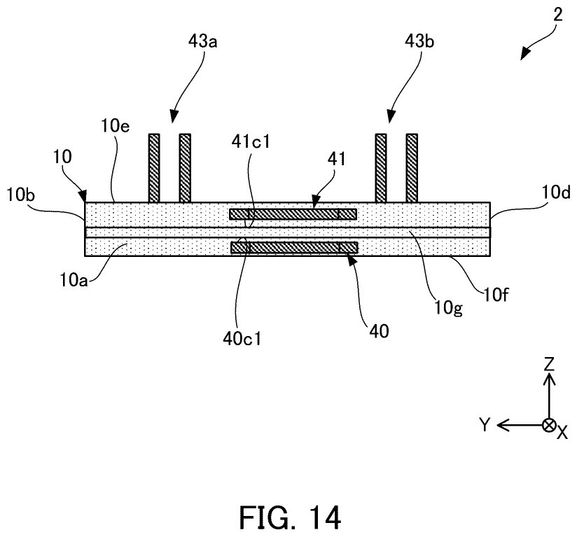

Hereinafter, semiconductor devices 1 according to modifications will be described. First, an individual semiconductor module 2 according to modification 1 will be described with reference to FIG. 14. FIG. 14 is a side view (Z-Y surface) of a semiconductor module included in a semiconductor device according to the embodiment (modification 1). As illustrated in FIG. 14, in the case of the individual semiconductor module 2 according to modification 1, a positive terminal 40 and a negative terminal 41 extending from a long side surface 10a are formed to face each other. The positive terminal 40 and the negative terminal 41 may each have a different shape inside a sealing body 10 of the semiconductor module 2 such that the positive terminal 40 and the negative terminal 41 face each other.

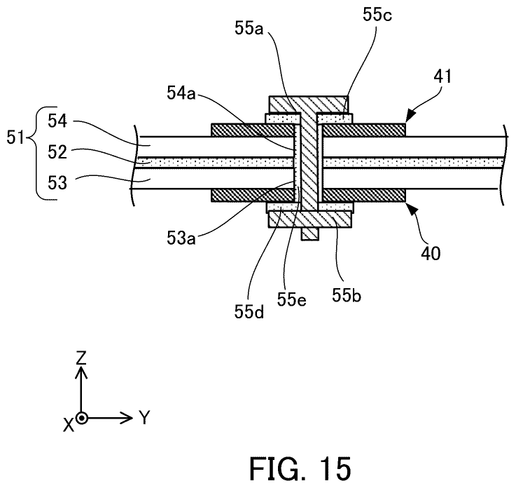

Next, coupling of the individual semiconductor module 2 and a capacitor 5 will be described with reference to FIG. 15. FIG. 15 is a sectional view of a coupling part of to the embodiment the semiconductor device according (modification 1). FIG. 15 corresponds to the sectional view in FIG. 12 taken along the dashed-dotted line X-X in FIGS. 1 and 2 when the individual semiconductor module 2 according to modification 1 and the capacitor 5 are coupled to each other.

An insulating layer 52 of a wiring terminal 51 included in the capacitor 5 according to modification 1 is also sandwiched by a positive conductive layer 53 and a negative conductive layer 54. The positive conductive layer 53 and the negative conductive layer 54 according to modification 1 have positive fastening holes 53a and negative fastening holes 54a, respectively, at their respective parts in a different way from those formed in the positive conductive layer 53 and the negative conductive layer 54 according to the embodiment. In addition, the positive conductive layer 53 and the negative conductive layer 54 according to modification 1 do not have negative opening holes 53b and positive opening holes 54b.

The long side surfaces 10a of a plurality of (herein, for example, three) semiconductor modules 2 are set to face a long side surface 50a of the capacitor 5, and the plurality of semiconductor modules 2 are moved toward the capacitor 5. The wiring terminal 51 of the capacitor 5 is sandwiched by the positive terminals 40 and the negative terminals 41 of the plurality of semiconductor modules 2. A tip of the insulating layer 52 is inserted into (stored in) storage grooves 10g in the long side surfaces 10a of the semiconductor modules 2.

After the wiring terminal 51 of the capacitor 5 is attached between the positive terminal 40 and the negative terminal 41 of the individual semiconductor module 2, a bolt 55a is inserted into a fastening hole 41d in the individual negative terminal 41, a negative fastening hole 54a in the negative conductive layer 54, a positive fastening hole 53a in the positive conductive layer 53, and a fastening hole 40d in the individual positive terminal 40, as illustrated in FIG. 15. The lower end part of each bolt 55a is exposed to the outside in the fastening hole 40d in the corresponding positive terminal 40, and a nut 55b is fastened to the lower end part.

As in the embodiment, the inductance of this semiconductor device 1 including the semiconductor modules 2 and the capacitor 5 is also reduced. In modification 1, insulating members 55c, 55d, and 55e are applied to the gap between a bolt 55a and a corresponding negative terminal 41, the gap between a nut 55b and a corresponding positive terminal 40, an individual fastening hole 41d, an individual negative fastening hole 54a, an individual positive fastening hole 53a, and an individual fastening hole 40d. Thus, the insulation between the individual negative terminal 41 and the individual positive terminal 40 is maintained.

### Modification 2

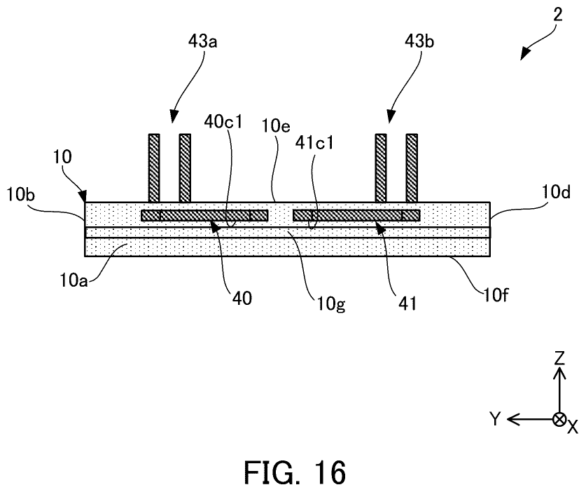

An individual semiconductor module 2 according to modification 2 will be described with reference to FIG. 16. FIG. 16 is a side view (Z-Y surface) of a semiconductor module included in a semiconductor device according to the embodiment (modification 2). In the case of the individual semiconductor module 2 according to modification 2, a positive terminal 40 and a negative terminal 41 extending from a long side surface 10a are aligned in the Y directions in side view as illustrated in FIG. 16. The positive terminal 40 and the negative terminal 41 may each have a different shape inside a sealing body 10 of the semiconductor module 2 such that the positive terminal 40 and the negative terminal 41 are aligned in the ±Y directions.

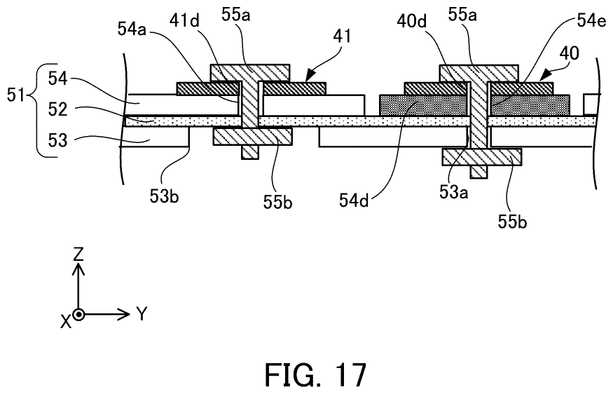

Next, coupling of the individual semiconductor module 2 and a capacitor 5 will be described with reference to FIG. 17. FIG. 17 is a sectional view of a coupling part of the semiconductor device according to the embodiment (modification 2). FIG. 17 corresponds to the sectional view taken along the dashed-dotted line X-X in FIG. 13 when the individual semiconductor module 2 according to modification 2 and the capacitor 5 are coupled to each other.

An insulating layer 52 of a wiring terminal 51 included in the capacitor 5 according to modification 2 is also sandwiched by a positive conductive layer 53 and a negative conductive layer 54. The positive conductive layer 53 according to modification 2 is the same as the positive conductive layer 53 according to the embodiment. However, unlike the negative conductive layer 54 according to the embodiment, the negative conductive layer 54 according to modification 2 has openings at parts that are in the contact with the positive terminals 40, and floating wires 54d are formed. The floating wires 54d are away from the other parts of the negative conductive layer 54 and are electrically isolated. The thickness of the individual floating wire 54d is the same as the thickness of the negative conductive layer 54. The individual floating wire 54d has a floating fastening hole 54e. No positive opening holes 54b are formed in the negative conductive layer 54 according to modification 2.

In the case of this wiring terminal 51, a negative fastening hole 54a in the negative conductive layer 54 corresponds to a negative opening hole 53b in the positive conductive layer 53. In addition, a floating fastening hole 54e in a floating wire 54d included in the negative conductive layer 54 corresponds to a positive fastening hole 53a in the positive conductive layer 53.

The long side surfaces 10a of a plurality of (herein, for example, three) semiconductor modules 2 are set to face a long side surface 50a of the capacitor 5, and the plurality of semiconductor modules 2 are moved toward the capacitor 5. The positive terminals 40 and the negative terminals 41 of the plurality of semiconductor modules 2 are disposed on the front side of the wiring terminal 51 of the capacitor 5. A tip of the insulating layer 52 is inserted into (stored in) storage grooves 10g in the long side surfaces 10a of the semiconductor modules 2.

After the positive terminals 40 and the negative terminals 41 of the semiconductor modules 2 are disposed on the wiring terminal 51 of the capacitor 5, a bolt 55a is inserted into a fastening hole 41d in the individual negative terminal 41 and into a negative fastening hole 54a in the negative conductive layer 54, as illustrated in FIG. 17. The lower end part of each bolt 55a is exposed to the outside in a negative opening hole 53b in the positive conductive layer 53, and a nut 55b is fastened to the lower end part.

In addition, a bolt 55a is inserted into a fastening hole 40d in the individual positive terminal 40, a floating fastening hole 54e in the individual floating wire 54d, and a positive fastening hole 53a in the positive conductive layer 53. The lower end part of each bolt 55a is exposed to the outside in a positive fastening hole 53a in the positive conductive layer 53, and a nut 55b is fastened to the lower end part.

As in the embodiment, the inductance of this semiconductor device 1 including the semiconductor modules 2 and the capacitor 5 is also reduced.

According to the disclosed technique, the inductance is reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a wiring terminal that includes an insulating layer, a first conductive layer formed on one main surface of the insulating layer, and a second conductive layer formed on another main surface of the insulating layer, the insulating layer having an insulating peripheral side that extends more outwardly than a conductive peripheral side of each of the first conductive layer and the second conductive layer; and
a semiconductor module, wherein the semiconductor module includes
a semiconductor chip having a first electrode and a second electrode,
a first terminal electrically connected to the first electrode, the first terminal including a first end part having a first contact surface in contact with the first conductive layer of the wiring terminal
a second terminal electrically connected to the second electrode, the second terminal including a second end part having a second contact surface, the second contact surface being away from the first end part, being parallel to the first contact surface and being in contact with the second conductive layer of the wiring terminal, and
a fixed part, having a basal surface which faces the insulating peripheral side of the wiring terminal and from which the first end part and the second end part extend to an outside of the fixed part in a same direction, the fixing part fixing inside thereof positions of the first terminal and the second terminal with respect to a position of the semiconductor chip, and having a recess in the basal surface between the first end part and the second end part, the insulating peripheral side of the insulating layer of the wiring terminal being inserted into the recess.

2. The semiconductor device according to claim 1, wherein the fixed part is a sealing member.

3. The semiconductor device according to claim 2, wherein
the first end part and the second end part each have a flat plate shape and are parallel to each other and orthogonal to the basal surface,
the first end part and the second end part are disposed on the basal surface such that a first width direction of a first width of the first end part and a second width direction of a second width of the second end part are the same and are parallel to the basal surface, and
the recess extends in the first width direction and the second width direction.

4. The semiconductor device according to claim 3, wherein the recess extends across the basal surface to penetrate through the fixed part.

5. The semiconductor device according to claim 4, wherein the first end part and the second end part are located at the basal surface at positions not overlapping each other in a direction orthogonal to the first width direction.

6. The semiconductor device according to claim 1, wherein the conductive peripheral side of each of the first conductive layer and the second conductive layer of the wiring terminal is in contact with the basal surface of the semiconductor module.

7. The semiconductor device according to claim 1, further comprising a capacitor including the wiring terminal.

8. A semiconductor module, comprising:
a first semiconductor chip which includes a first electrode and a second electrode;
a second semiconductor chip which includes a third electrode electrically connected to the first electrode of the first semiconductor chip and includes a fourth electrode;
a first terminal which includes a first end part having a first contact surface, the first terminal being electrically connected to the first electrode of the first semiconductor chip;
a second terminal electrically connected to the fourth electrode of the second semiconductor chip, the second terminal including a second end part having a second contact surface that is away from the first end part and is parallel to the first contact surface; and
a fixed part having a basal surface from which the first end part and the second end part extend in a same direction to outside of the fixed part, the fixed part fixing inside thereof positions of the first terminal and the second terminal with respect to positions of the first semiconductor chip and the second semiconductor chip, and having a recess in the basal surface between the first end part and the second end part.
